(19) United States
(12) Patent Application Publication
(10) Pub. No.: US 2023/0387479 A1
(43) Pub. Date: Nov. 30, 2023

(54) BATTERY SWELLING DETERMINATIONS

(71) Applicant: Hewlett-Packard Development Company, L.P., Spring, TX (US)

(72) Inventors: Fangyong Dai, Spring, TX (US); Qijun Chen, Spring, TX (US); Sze Hau Loh, Spring, TX (US)

(21) Appl. No.: 17/824,170

(22) Filed: May 25, 2022

(51) Int. Cl. H01M 10/42; H01M 10/0525; H01M 10/48; G01R 27/26; G01R 31/392; G01R 31/36

(52) U.S. Cl. CPC H01M 10/425; H01M 10/0525; H01M 10/48; G01R 27/2605; G01R 31/392; G01R 31/3648

(57) ABSTRACT

Example implementations relate to battery swelling determinations. In some examples, an electronic device can include a battery including a first surface and a second surface, where the second surface is opposite the first surface, a first conductor located on the first surface of the battery, and a second conductor located on the second surface of the battery, where the battery is to act as a dielectric medium such that a capacitance is generated by the electronic device via the first conductor, the second conductor, and the battery.

### BACKGROUND

Users of computing devices may utilize their computing devices for various purposes. A computing device can allow a user to utilize computing device operations for work, education, gaming, multimedia, and/or other general use. Certain computing devices can be portable to allow a user to carry or otherwise bring with the computing device while in a mobile setting, while other computing devices may not be portable but allow a user to utilize the computing device in an office or home setting. Such computing devices may be utilized for work, education, gaming, multimedia, and/or other general use in mobile settings, office settings, home settings, and/or in any other setting.

### BRIEF DESCRIPTION OF THE DRAWINGS

FIG. 1 illustrates an example of an electronic device for battery swelling determinations consistent with the disclosure.

FIG. 2A illustrates an example of an electronic device having a first conductor and a second conductor connected to a battery via adhesive consistent with the disclosure.

FIG. 2B illustrates an example of an electronic device having a first conductor and a second conductor connected to a battery via fasteners consistent with the disclosure.

FIG. 2C illustrates an example of an electronic device having a first conductor and a second conductor integrated within a material comprising surfaces of the battery consistent with the disclosure.

FIG. 3 illustrates an example of a computing device for battery swelling determinations consistent with the disclosure.

FIG. 4 illustrates an example of an electronic device having a battery swelling consistent with the disclosure.

FIG. 5 illustrates a block diagram of an example system for battery swelling determinations consistent with the disclosure.

### DETAILED DESCRIPTION

A user may utilize a computing device for various purposes, such as for business and/or recreational use. As used herein, the term “computing device” refers to an electronic system having a processing resource, memory resource, and/or an application-specific integrated circuit (ASIC) that can process information. A computing device can be, for example, a laptop computer, a notebook, a desktop, a tablet, an all-in-one (AIO) computer, and/or a mobile device, among other types of computing devices.

Certain computing devices can be utilized in a mobile setting. In such a mobile setting, a computing device may utilize a battery in order to provide power to the computing device. As used herein, the term “battery” refers to a device which stores electrical energy. The stored electrical energy in the battery may be utilized by the computing device for performing computing device operations.

In some examples, the battery utilized by the computing device can be a lithium-ion battery. As used herein, the term “lithium-ion battery” refers to a type of rechargeable battery composed of a cell in which lithium ions move from a negative electrode through an electrolyte to a positive electrode during discharge and back when charging.

During operation of a battery (e.g., such as during charge or discharge), the electrolyte in the cell can degrade. As a result, a gas can be generated within the cell. Generation of this gas can cause the lithium-ion battery to swell. For example, as the battery is used over time, gas generated in the cell which can cause the battery to increase in size. Such swelling can be further exacerbated by prolonged exposure of the battery to heat and/or overcharging the battery (e.g., keeping the battery at a high state of charge for long periods of time by keeping the computing device connected to power).

Swelling of the battery is not reversible and can lead to eventual failure of the battery. Therefore, quantifying an amount of swelling during operation of the battery can allow for mitigating measures to be taken to slow the swelling of the battery.

Battery swelling determinations can allow for a mechanism to quantify the swell amount of a battery utilizing a capacitance measurement. Since the capacitance measurement can be correlated with a particular amount of swell, actions can be taken to mitigate the swell of the battery. Such an approach can allow for early swell detection in a battery with a small amount of parts while maintaining a small form factor for the battery for use in mobile computing devices.

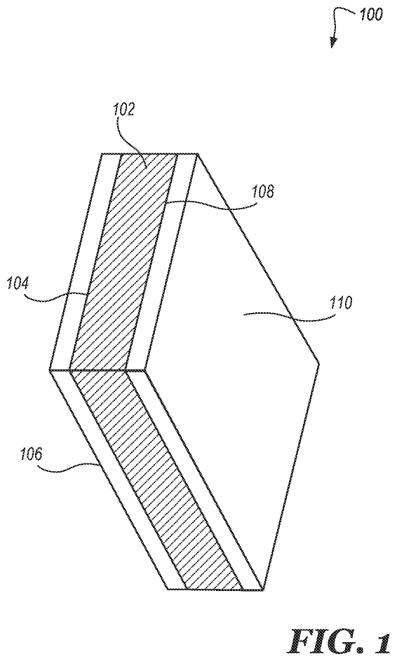

FIG. 1 illustrates an example of an electronic device for battery swelling determinations consistent with the disclosure. As illustrated in FIG. 1, the electronic device 100 can include a battery 102, a first conductor 106, and a second conductor 110.

As mentioned above, the electronic device 100 can be utilized in a computing device. Such computing devices may be utilized in mobile settings. Accordingly, the electronic device 100 can utilize a battery 102 to power the computing device in such mobile settings.

The battery 102 can, in some examples, be a lithium-ion battery. Lithium-ion batteries can include a high energy density, little to no memory effect, and have a low self-discharge as compared to other types of batteries. Accordingly, they can be well suited for use in mobile computing devices. Types of lithium-ion battery chemistries may include lithium cobalt oxide, lithium manganese oxide, lithium nickel manganese cobalt oxide, lithium iron phosphate, lithium nickel cobalt aluminum oxide, lithium titanate, and/or any other type of lithium-ion battery chemistry. In other words, the battery 102 can include any type of lithium-ion chemistry makeup. Accordingly, battery swelling determinations according to the disclosure can allow for a determination of swelling in any chemistry makeup of the battery 102.

Although the battery 102 is described as being a lithium-ion battery, examples of the disclosure are not so limited. For example, the battery 102 can be a nickel cadmium battery, a nickel metal hydride battery, and/or any other type of battery.

In some examples, the battery 102 can be a pouch cell lithium-ion battery. As used herein, the term “pouch cell battery” refers to a battery having a flexible outer layer. For example, the battery 102 can have a flexible outer layer. The flexible outer layer can be comprised of aluminum plastic film, among other types of material. Such a pouch cell battery can allow for a lightweight and small form-factor battery, as compared with batteries having a rigid outer casing.

As illustrated in FIG. 1, the battery 102 includes a first surface 104 and a second surface 108. The first surface 104 and the second surface 108 are located opposite from each other. The first surface 104 and the second surface 108 are the surfaces of the battery 102 which have the largest dimensions of the surfaces of the battery 102. In other words, the first surface 104 and the second surface 108 are the surfaces of the battery 102 which are the largest surfaces.

The battery 102 includes a first conductor 106 located on the first surface 104 of the battery 102 and a second conductor 110 located on the second surface 108 of the battery 102. The first surface 104 and the second surface 108 are selected as the largest dimensions of the surfaces of the battery 102 in order to allow for the first conductor 106 and the second conductor 110 to be large as possible relative to the size of the surfaces of the battery 102. Such dimensions for the first conductor 106 and the second conductor 110 can allow for a more precise capacitance measurement as compared with conductors of a smaller size than the first conductor 106 and the second conductor 110.

In some examples, the first conductor 106 and the second conductor 110 can be conductive plates. As used herein, the term “conductive plate” refers to a rigid sheet of material having the ability to conduct electricity. The conductive plates can be material having sufficient electrical conductivity for battery swelling determinations as described herein. For example, the first conductor 106 and the second conductor 110 can be metallic plates made of aluminum, copper, titanium, and/or any other conductive material (e.g., metal, conductive polymer, etc.).

In some examples, the first conductor 106 and the second conductor 110 can be conductive foil. As used herein, the term “conductive foil” refers to a thin flexible sheet of material having the ability to conduct electricity. For example, the first conductor 106 and the second conductor 110 can be flexible metallic plates made of aluminum, copper, titanium, and/or any other conductive material (e.g., metal, conductive polymer, etc.).

Although the first conductor 106 and the second conductor 110 are described above as being both conductive plates or conductive foil, examples of the disclosure are not so limited. For example, the first conductor 106 and the second conductor 110 can be combinations thereof (e.g., the first conductor 106 can be a conductive plate and the second conductor 110 can be a conductive foil, or vice versa).

As illustrated in FIG. 1, the first conductor 106 and the second conductor 110 cover the entirety of the first surface 104 and the second surface 108, respectively, of the battery 102. However, examples of the disclosure are not so limited. For example, the first conductor 106 and/or the second conductor 110 can cover a portion of the first surface 104 and/or the second surface 108, respectively.

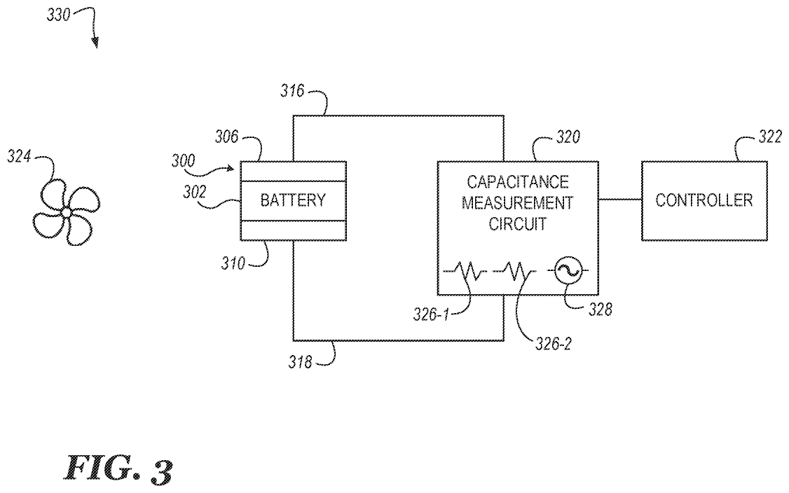

As illustrated in FIG. 1, the battery 02 is located between the first conductor 106 and the second conductor 110. The battery 102 can act as a dielectric medium such that a capacitance is generated by the electronic device 100 via the first conductor 106, the second conductor 110, and the battery 102 in response to a voltage being applied across the first conductor 106 and the second conductor 110. As used herein, the term “dielectric medium” refers to an electrical insulator. As used herein, the term “capacitance” refers to the ratio of the amount of electric charge stored on a conductor to a difference in electric potential. In other words, as illustrated in FIG. 1, the electronic device 100 can act as a capacitor when a voltage is applied across the first conductor 106 and the second conductor 110. As used herein, the term “capacitor” refers to a device that stores electrical energy in an electric field. The capacitance of the electronic device 100 can be utilized to determine an amount of swell of the battery 102, as is further described in connection with FIG. 3.

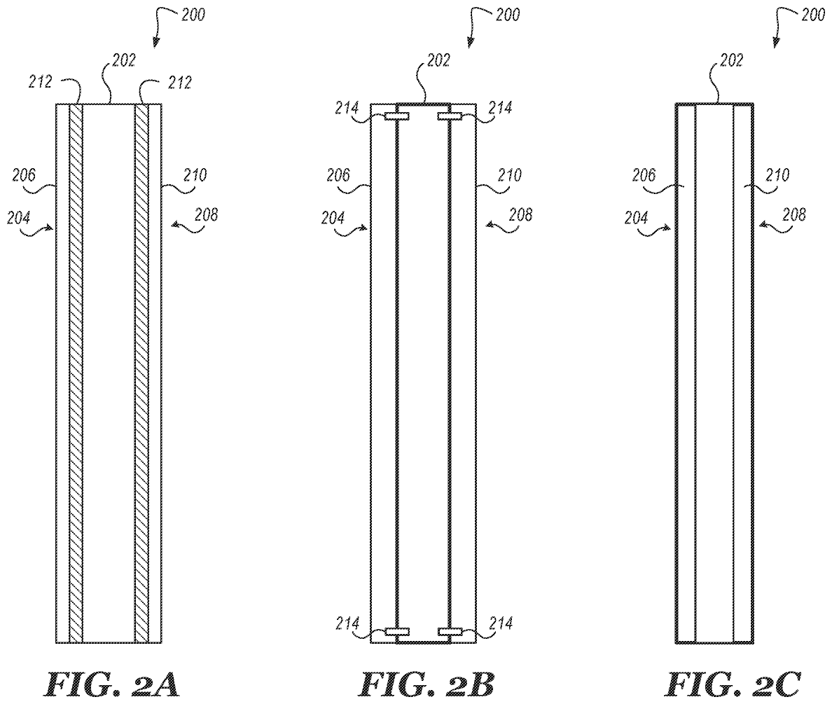

FIG. 2A illustrates an example of an electronic device 200 having a first conductor 206 and a second conductor 210 connected to a battery 202 via adhesive 212 consistent with the disclosure. As illustrated in FIG. 2A, the electronic device 200 can include the battery 202, the first conductor 206, and the second conductor 210.

The first conductor 206 and the second conductor 210 can be connected to the battery 202 in various ways. In some examples, the first conductor 206 is connected to the first surface 204 of the battery 202 via adhesive 212 and the second conductor 210 is connected to the second surface 208 of the battery 202 via adhesive 212, As used herein, the term “adhesive” refers to a substance applied to one or both surfaces of objects in order to bind them together. In some examples, the adhesive 212 can covers an entirety of the first surface 204 and the second surface 208 of the battery 202 in order to connect the first conductor 206 and the second conductor 210 to the battery 202. In some examples, the adhesive 212 can cover portions of the first surface 204 and the second surface 208 of the battery 202 in order to connect the first conductor 206 and the second conductor 210 to the battery 202.

FIG. 2B illustrates an example of an electronic device 200 having a first conductor 206 and a second conductor 210 connected to a battery 202 via fasteners 214 consistent with the disclosure. As illustrated in FIG. 2B, the electronic device 200 can include the battery 202, the first conductor 206, and the second conductor 210.

In some examples, the first conductor 206 is connected to the first surface 204 of the battery 202 via fasteners 214 and the second conductor 210 is connected to the second surface 208 of the battery 202 via fasteners 214. As used herein, the term “fastener” refers to a means to mechanically join objects together. The fasteners 214 can be, for example, threaded fasteners (e.g., screws, bolts/nuts), clasps, clips, pins, retaining rings, rivets, and/or any other type of fastener. In some examples, the first conductor 206 is connected to the first surface 204 of the battery 202 and the second conductor 210 is connected to the second surface 208 of the battery 202 via crimping, welding, soldering, and/or brazing.

FIG. 2C illustrates an example of an electronic device 200 having a first conductor 206 and a second conductor 210 integrated within a material comprising surfaces of the battery 202 consistent with the disclosure. As illustrated in FIG. 2B, the electronic device 200 can include the battery 202, the first conductor 206, and the second conductor 210.

As illustrated in FIG. 2C, the first conductor 206 is integrated within a material comprising the first surface 204 of the battery 202 and the second conductor 210 is integrated within a material comprising the second surface 208 of the battery 202. As used herein, the term “integrated within” refers to being incorporated as a whole. For instance, in an example in which the material comprising the first surface 204 and the second surface 208 of the battery 202 is an aluminum plastic film and the first conductor 206 and the second conductor 210 are of an aluminum foil material, the aluminum foil material can be incorporated within the aluminum plastic film such that it would appear to be a single unitary material.

FIG. 3 illustrates an example of a computing device 330 for battery swelling determinations consistent with the disclosure. As illustrated in FIG. 3, the computing device 330 includes an electronic device 300, a capacitance measurement circuit 320, a controller 322, and a fan 324.

As previously described above, the electronic device 300 can be included in a computing device 330. Such a computing device 330 may be utilized in a mobile setting, and the battery 302 may be utilized to provide power to the computing device 330 in such a mobile setting.

The battery 302 can have a first conductor 306 located on a first surface of the battery and a second conductor 310 located on a second surface of the battery, where the second surface is opposite the first surface. As illustrated in FIG. 1, the first conductor 306 can include a first electrode 316. As used herein, the term “electrode” refers to an electrical conductor. The first electrode 316 can be connected to the electronic device 300 so as to transmit a signal, apply a voltage, etc. Additionally, the second conductor 310 can include a second electrode 318 which can be connected to the electronic device 300 so as to transmit a signal, apply a voltage, etc.

The computing device 330 can include a capacitance measurement circuit 320. As used herein, the term “capacitance measurement circuit” refers to a group of components connected by conductive wires or traces through which electric current can flow. The first electrode 316 and the second electrode 318 can be connected to the capacitance measurement circuit 320. The capacitance measurement circuit 320 can be utilized to determine a capacitance of the electronic device 300, as is further described herein.

The computing device 330 further includes a controller 322. In order to measure a capacitance of the battery 302, the first conductor 306, and the second conductor 310 (e.g., the electronic device 300), the controller 322 can cause a voltage to be applied across the first conductor 306 and the second conductor 310. The controller 322 can cause the voltage to be applied across the first conductor 306 and the second conductor 310 via two resistors (e.g., resistors 326-1 and 326-2) with known resistance values. The voltage applied can be an alternating current (AC) voltage (e.g., applied via AC source 328) with a known (e.g., first) amplitude at a high frequency. In response to the applied voltage, the capacitance measurement circuit 320 can receive a signal.

In response to the AC voltage being applied across the first conductor 306 and the second conductor 310, the controller 322 can receive a signal from the capacitance measurement circuit 320. The signal can be an AC signal (e.g., in the example of an AC voltage applied across the first conductor 306 and the second conductor 310 via the two resistors 326-1, 326-2). The signal can be a measured (e.g., second) amplitude which is affected by the electronic device 300, as is further described herein.

The controller 322 can determine a capacitance of the battery 302, the first conductor 306, and the second conductor 310 via the signal. In some examples, the capacitance measurement circuit 320 can include a capacitance sensor. As used herein, the term “capacitance sensor” refers to a device to detect capacitance in its environment and transmit the detected capacitance for processing and/or analysis. For example, based on the signal, the capacitance sensor can determine a capacitance of the electronic device 300.

In some examples, the capacitance measurement circuit 320 can include circuitry to determine the capacitance of the electronic device 300 via a characteristic of the signal. For example, as described above, an AC voltage (e.g., a sine wave (e.g., 500 kilohertz)) may be injected by the AC source 328 of the capacitance measurement circuit across the first conductor 306 and the second conductor 310 via the two resistors (e.g., resistors 326-1 and 326-2) and an amplitude may be monitored.

The signal (e.g., the measured amplitude) can be received by the capacitance measurement circuit 320. The second amplitude received from the electronic device 300 (e.g., after the two resistors 326-1, 326-2) and measured by the capacitance measurement circuit 320 is less than the applied first amplitude. The decreased second amplitude is related to the capacitance of the electronic device 300. Utilizing the applied AC voltage (e.g., the first amplitude), the frequency, the measured AC voltage (e.g., the second amplitude), and the two known resistor values of resistors 326-1, 326-2, the controller 322 can determine the capacitance of the electronic device 300.

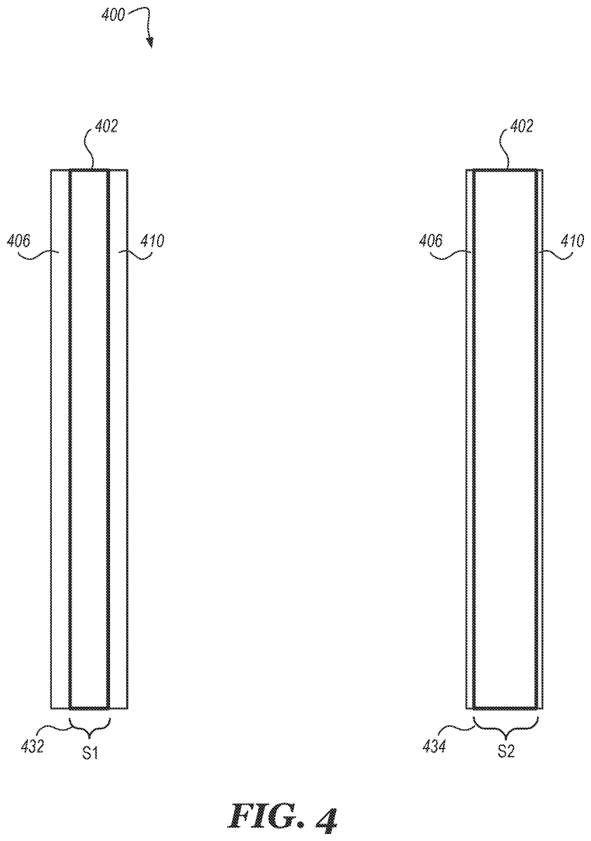

The capacitance of the electronic device 300 can be based on a permittivity of the battery 302, an area of overlap of the first conductor 306 and the second conductor 310, and a thickness of the battery 302 (e.g., as is further described in connection with FIG. 4) that defines a distance between the first conductor 306 and the second conductor 310. Such a relationship can be characterized by Equation 1 below:

$$C = \frac{ε A}{d} \qquad Equation 1$$

where C is capacitance, ε is permittivity of battery, A is an area of conductor overlap, and d is a distance between the conductors.

As illustrated by Equation 1 above, as the distance (e.g., d) between the first conductor 306 and the second conductor 310 increases (e.g., as the amount of swell of the battery 302 increases), the capacitance (e.g., C) decreases. That is, in response to the amount of swell increasing, the thickness of the battery 302 increases causing the capacitance of the electronic device 300 to decrease. Further, the release of gas can also decrease the permittivity of the battery 302 causing the capacitance of the electronic device 300 to decrease as well. The amount of swell corresponds to the thickness of the battery 302.

For example, the controller 322 can determine the capacitance of the electronic device 300 to be 3 nano-Farads (nF). Utilizing Equation 1 above, the distance (e.g., d) can be solved for utilizing the determined capacitance of the electronic device 300 to determine the amount of swell in the battery 302. As an example, the controller 322 can determine the capacitance of the electronic device 300 to be 3 nF, which can correspond to a particular thickness (e.g., 3 millimeters (mm)). The 3 mm thickness may be the thickness of the battery 302 at the beginning of its life cycle (e.g., when the battery 302 is new, in an original state).

In some examples, the swell can be determined based on a predetermined relationship between capacitance and amount of swell. For example, a correlation between a particular capacitance and an amount of swell can be known such that based on a determined capacitance, the controller 322 can determine the amount of swell.

The controller 322 can monitor the electronic device 300 for swell over a life cycle of the battery 302. For example, the controller 322 can determine the capacitance of the electronic device 300 and determine an amount of swell of the battery 302 based on the determined capacitance at a predetermined frequency (e.g., once every minute, hour, day, etc.).

As mentioned above, as the battery 302 is utilized throughout its lifecycle, swell can occur. Such swell may not be reversible. However, battery swelling determinations according to the disclosure can act to mitigate such swelling, as is further described herein.

For example, the controller can determine a capacitance of the electronic device 300 to be 1.4 nF. Utilizing Equation 1 above, the controller 322 can determine the amount of swell to be 3.6 mm. In other words, the controller can determine the battery 302 is 3.6 mm thick (e.g., an increase in thickness of 0.6 mm from the battery 302's original thickness in its original state). The controller can determine the swell of the battery 302 to exceed a first threshold level. For example, the first threshold level can be 3.5 mm, and the controller can determine that the swell of the battery 302 (e.g., 3.6 mm) has exceeded the first threshold level (e.g., 3.5 mm).

In response to the amount of swell exceeding the first threshold level, the controller 322 can decrease an amount of charge capacity the battery 302 can receive. As used herein, the term “charge capacity” refers to a total amount of energy a battery can store. For example, in its original state, the battery 302 may be charged to 100% charge capacity (e.g., 700 Watt hours per Liter (Wh/L)). The controller 322 can decrease the amount of charge capacity of the battery 302 to 90% (e.g., 630 Wh/L) in order to decrease the amount of charge the battery 302 can receive. Such an action can slow the swelling of the battery 302.

As another example, the controller can determine a capacitance of the electronic device 300 to be 0.8 nF. Utilizing Equation 1 above, the controller 322 can determine the amount of swell to be 4.2 mm. In other words, the controller can determine the battery 302 is 4.2 mm thick (e.g., an increase in thickness of 1.2 mm from the battery 302's original thickness in its original state). The controller can determine the swell of the battery 302 to exceed a second threshold level. For example, the second threshold level can be 4 mm, and the controller can determine that the swell of the battery 302 (e.g., 4.2 mm) has exceeded the second threshold level (e.g., 4 mm).

In response to the amount of swell exceeding the second threshold level, the controller 322 can cause a temperature mitigation event to occur to decrease a temperature of the battery 302. As mentioned above, when the battery 302 is exposed to high temperatures, swelling can be exacerbated. Accordingly, the controller 322 can cause a temperature mitigation event to occur to decrease the temperature of the battery 302 to slow the swelling of the battery 302. Such a temperature mitigation event can include, for example, causing a fan speed of a fan 324 to increase. The air flow generated by the fan 324 can cause the battery 302 to be cooled, decreasing the temperature of the battery 302.

As another example of the amount of swell exceeding the second threshold level, in response to the amount of swell exceeding the second threshold level, the controller 322 can cause a charge current to the battery to be decreased. As used herein, the term “charge current” refers to a net rate of flow of electrons supplied to a battery. When the battery 302 is being charged, heat may be generated. As mentioned above, when the battery 302 is exposed to high temperatures, swelling can be exacerbated. Accordingly, the controller 322 can decrease the charge current supplied to the battery 302 from a first amount to a second amount during charging to decrease the amount of heat generated by the battery 302 during charging in order to decrease the temperature of the battery 302 to slow the swelling of the battery 302.

Although decreasing the amount of charge capacity of the battery is associated with the first threshold and causing a temperature mitigation event to occur or decreasing the amount of charge current is associated with the second threshold as described above, examples of the disclosure are not so limited. For example, causing a temperature mitigation event to occur can be associated with the first threshold or decreasing the amount of charge current can be associated with the first threshold and decreasing the amount of charge capacity of the battery can be associated with the second threshold.

As a further example, the controller can determine a capacitance of the electronic device 300 to be 0.5 nF. Utilizing Equation 1 above, the controller 322 can determine the amount of swell to be 4.6 mm. In other words, the controller can determine the battery 302 is 4.6 mm thick (e.g., an increase in thickness of 1.6 mm from the battery 302's original thickness in its original state). The controller can determine the swell of the battery 302 to exceed a third threshold level. For example, the third threshold level can be 4.5 mm, and the controller can determine that the swell of the battery 302 (e.g., 4.6 mm) has exceeded the second threshold level (e.g., 4.5 mm).

In response to the amount of swell exceeding the third threshold level, the controller 322 can generate an alert to replace the battery 302. As mentioned above, swelling is not reversible. When the battery 302 swells to a certain size, the battery 302 may no longer be usable without safety concerns. If the battery 302 were to be perforated (e.g., due to over-swelling), a user of the computing device 330 may be exposed to hazardous gases and/or chemicals, Accordingly, the controller 322 can generate an alert to the user to notify the user to replace the battery 302. Such an alert can be an audible alert, a visual alert (e.g., generated and displayed on a display device associated with the computing device 330, not illustrated in FIG. 3), among other types of alerts.

FIG. 4 illustrates an example of an electronic device 400 having a battery swelling consistent with the disclosure, The electronic device 400 can include the battery 402, the first conductor 406, and the second conductor 410.

As previously described in connection with FIG. 3, the battery 402 can include an initial thickness 432. Such a thickness 432 is illustrated in FIG. 4 as S1. The thickness 432 indicated as S1 can be, for instance, 3 mm. The 3 mm thickness of the battery 402 may be the thickness of the battery 402 in its original state.

A controller can determine a capacitance of the battery 402 when the thickness 432 is at S1. For example, the capacitance of the battery 402 may be at 3 nF at thickness 432.

As illustrated in FIG. 4, over time the battery 402 may swell to thickness 434, indicated in FIG. 4 as S2. The thickness 434 indicated as S2 can be, for instance 4.2 mm. A controller can determine a capacitance of the battery 402 when the thickness 434 is at S2. For example, the capacitance of the battery 402 may be at 0.8 nF. In other words, as a result of the amount of swell of the battery 402 increasing from a first thickness 432 to a second thickness 434, the capacitance of the electronic device 400 decreases.

Although the swell in the battery 402 is indicated as a constant thickness 434 in FIG. 4, examples of the disclosure are not so limited. For example, the swell in the battery 402 may cause a bulge in one particular area of the battery 402 resulting in an inconsistent thickness 434 of the batter 402. In other words, the swell in the battery 402 may not be symmetrical or consistent across the entire battery 402. As described herein, the thickness (e.g., the swell) of the battery 402 is determined at the thickest portion of the battery 402.

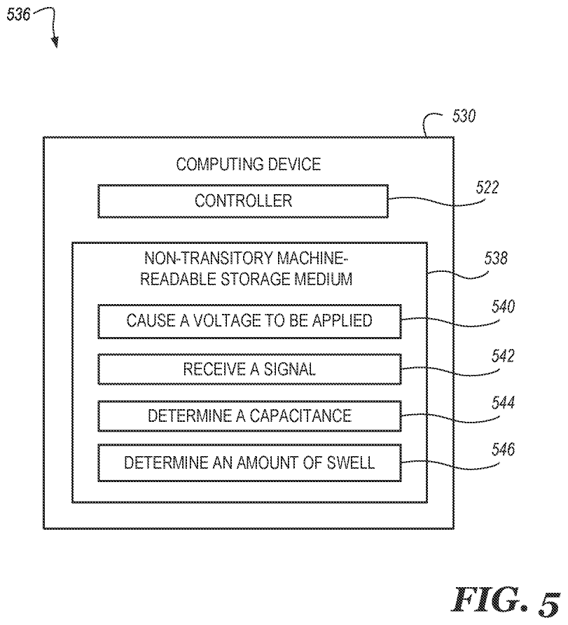

FIG. 5 illustrates a block diagram of an example system 536 for battery swelling determinations consistent with the disclosure. In the example of FIG. 5, system 536 includes a controller 522 and a non-transitory machine-readable storage medium 538. The controller 522 can include a processing resource (e.g., not illustrated in FIG. 5). The following descriptions refer to a single processing resource and a single machine-readable storage medium, the descriptions may also apply to a system with multiple processors and multiple machine-readable storage mediums. In such examples, the instructions may be distributed across multiple machine-readable storage mediums and the instructions may be distributed across multiple processors. Put another way, the instructions may be stored across multiple machine-readable storage mediums and executed across multiple processors, such as in a distributed computing environment.

The processing resource may be a central processing unit (CPU), microprocessor, and/or other hardware device suitable for retrieval and execution of instructions stored in a non-transitory machine-readable storage medium 538. In the particular example shown in FIG. 5, the processing resource may receive, determine, and send instructions 540, 542, 544, 546. As an alternative or in addition to retrieving and executing instructions, the processing resource may include an electronic circuit comprising a number of electronic components for performing the operations of the instructions in the non-transitory machine-readable storage medium 538. With respect to the executable instruction representations or boxes described and shown herein, it should be understood that part or all of the executable instructions and/or electronic circuits included within one box may be included in a different box shown in the figures or in a different box not shown.

The non-transitory machine-readable storage medium 538 may be any electronic, magnetic, optical, or other physical storage device that stores executable instructions. Thus, the non-transitory machine-readable storage medium 538 may be, for example, Random Access Memory (RAM), an Electrically-Erasable Programmable Read-Only Memory (EEPROM), a storage drive, an optical disc, and the like. The executable instructions may be “installed” on the system 536 illustrated in FIG. 5. The non-transitory machine-readable storage medium 538 may be a portable, external or remote storage medium, for example, that allows the system 536 to download the instructions from the portable/external/remote storage medium, In this situation, the executable instructions may be part of an “installation package”.

Cause instructions 540, when executed by the processing resource, may cause system 536 to cause a voltage to be applied across a first conductor located on a first surface of a battery and a second conductor located on a second surface of the battery of the computing device 530. The battery can be located between the first conductor and the second conductor.

Receive instructions 542, when executed by the processing resource, may cause system 536 to receive a signal from a capacitance measurement circuit in response to the voltage being applied. The capacitance measurement circuit can be connected to the battery via a first electrode connected to the first conductor and a second electrode connected to the second conductor.

Determine instructions 544, when executed by the processing resource, may cause system 536 to determine a capacitance of the battery via the signal. The signal may be an AC signal.

Determine instructions 546, when executed by the processing resource, may cause system 536 to determine an amount of swell of the battery based on the determined capacitance. For example, a predetermined relationship between capacitance and amount of swell may be known. Accordingly, the determined capacitance can be used to determine an amount of swell of the battery.

In the foregoing detailed description of the disclosure, reference is made to the accompanying drawings that form a part hereof, and in which is shown by way of illustration how examples of the disclosure may be practiced. These examples are described in detail to enable those of ordinary skill in the art to practice the examples of this disclosure, and it is to be understood that other examples may be utilized and that process, electrical, and/or structural changes may be made without departing from the scope of the disclosure.

The figures herein follow a numbering convention in which the first digit corresponds to the drawing figure number and the remaining digits identify an element or component in the drawing. Similar elements or components between different figures may be identified by the use of similar digits. For example, 102 may reference element “02” in FIG. 1, and a similar element may be referenced as 202 in FIG. 2A.

Elements illustrated in the various figures herein can be added, exchanged, and/or eliminated so as to provide a plurality of additional examples of the disclosure. In addition, the proportion and the relative scale of the elements provided in the figures are intended to illustrate the examples of the disclosure and should not be taken in a limiting sense. As used herein, “a plurality of” an element and/or feature can refer to more than one of such elements and/or features.

What is claimed is:

1. An electronic device, comprising:
a battery including a first surface and a second surface, wherein the second surface is opposite the first surface;
a first conductor located on the first surface of the battery; and
a second conductor located on the second surface of the battery;
wherein the battery is to act as a dielectric medium such that a capacitance is generated by the electronic device via the first conductor, the second conductor, and the battery.

2. The electronic device of claim 1, wherein the battery is a pouch cell lithium-ion battery.

3. The electronic device of claim 1, wherein:
the first conductor includes a first electrode and the second conductor includes a second electrode; and
the first electrode and the second electrode are connected to a capacitance measurement circuit to determine the capacitance of the electronic device.

4. The electronic device of claim 1, further comprising a controller to determine, based on the capacitance, an amount of swell of the battery.

5. The electronic device of claim 1, wherein the first conductor and the second conductor are conductive plates.

6. The electronic device of claim 1, wherein the first conductor and the second conductor are conductive foil.

7. The electronic device of claim 1, wherein the first conductor is connected to the first surface of the battery and the second conductor is connected to the second surface of the battery via adhesive.

8. The electronic device of claim 1, wherein the first conductor is connected to the first surface of the battery and the second conductor is connected to the second surface of the battery via fasteners.

9. The electronic device of claim 1, wherein:
the first conductor is integrated within a material comprising the first surface of the battery; and
the second conductor is integrated within a material comprising the second surface of the battery.

10. The electronic device of claim 1, wherein an amount of swell is a thickness of the battery such that in response to the amount of swell of the battery increasing from a first thickness to a second thickness, the capacitance of the electronic device decreases.

11. A computing device; including:
a capacitance measurement circuit;
a battery including a first surface and a second surface, wherein the second surface is opposite the first surface;
a first conductor located on the first surface of the battery; and
a second conductor located on the second surface of the battery;
a controller to:
receive a signal from the capacitance measurement circuit in response to a voltage being applied across the first conductor and the second conductor;
determine a capacitance of the battery; the first conductor; and the second conductor via the signal; and
determine an amount of swell of the battery based on the determined capacitance.

12. The computing device of claim 11, wherein:
the capacitance of the battery, the first conductor, and the second conductor is based on a permittivity of the battery, an area of overlap of the first conductor and the second conductor, and a thickness of the battery that defines a distance between the first conductor and the second conductor; and
the amount of swell corresponds to the thickness of the battery.

13. The computing device of claim 12, wherein in response to the amount of swell increasing, the thickness of the battery increases and a permittivity of the battery decreases causing the capacitance to decrease.

14. The computing device of claim 11, wherein in response to the amount of swell exceeding a threshold level, the controller is to decrease an amount of charge capacity the battery can receive.

15. The computing device of claim 11, wherein in response to the amount of swell exceeding a threshold level, the controller is to cause a temperature mitigation event to occur to decrease a temperature of the battery.

16. The computing device of claim 11, wherein in response to the amount of swell exceeding a threshold level, the controller is to decrease a charge current supplied to the battery from a first amount to a second amount.

17. The computing device of claim 11, wherein in response to the amount of swell exceeding a threshold level, the controller is to generate an alert to replace the battery.

18. A non-transitory machine-readable storage medium including instructions that when executed cause a controller of a computing device to:
cause a voltage to be applied across a first conductor located on a first surface and a second conductor located on a second surface of a battery of the computing device, wherein the battery is located between the first conductor and the second conductor;
receive a signal from a capacitance measurement circuit in response to the voltage being applied;
determine a capacitance of the battery, the first conductor, and the second conductor via the signal; and
determine an amount of swell of the battery based on the determined capacitance.

19. The non-transitory machine-readable storage medium of claim 18, including instructions to determine the capacitance from a group consisting of:
a capacitance sensor; and
a characteristic of the signal.

20. The non-transitory machine-readable storage medium of claim 18, including instructions to receive the signal in a form of an alternating-current (AC) signal.
